(19) United States
(12) Patent Application Publication
(10) Pub. No.: US 2025/0299925 A1
(43) Pub. Date: Sep. 25, 2025

(54) SUBSTRATE DAMAGE REDUCING TYPE OF AN APPARATUS FOR ETCHING AN ATOMIC LAYER

(71) Applicant: VM Inc., Icheon-si (KR)

(72) Inventors: Sang Woo LEE, Suwon-si (KR); Woo Hyung CHOI, Seongnam-si (KR); Joong Hyeon AHN, Hwaseong-si (KR)

(21) Appl. No.: 19/037,750

(22) Filed: Jan. 27, 2025

(30) Foreign Application Priority Data
Mar. 22, 2024 (KR) 10-2024-0039469

(51) Int. Cl. H01J 37/32; H01L 21/67

(52) U.S. Cl. CPC H01J 37/32357; H01J 37/3244; H01J 2237/334; H01L 21/67069

(57) ABSTRACT

An apparatus for etching an atomic layer comprises a shower head 11 for guiding a plasma generated from a remote plasma source RPS into a chamber C; a ceramic sheet 12 placed on an upper surface of a supporting block BD on which a wafer W is fixed, and having a plurality grooves G_1 to G_N; a temperature regulating block 16 placed under the ceramic sheet 12; and a DC applying pin 15 whose end part protrudes to at least one among the plurality of grooves G_1 to G_N.

### BACKGROUND OF THE INVENTION

### Field of the Invention

The present invention relates to a substrate damage reducing type of an apparatus for etching an atomic layer, in particular the apparatus to reducing the substrate damage using a remote plasma and DC pulse bias.

### Description of the Related Art

As a device becomes more highly integrated, an expectation and requirement for a dry etching have been changed gradually stringently. In case of a logic device, a fin field effect transistor (FinFET) has already been commercialized and a gate all around (GAA) has been being considered as a next generation device, and a pattern size has already exceeded 3 nm to reach tens atomic level on being calculated in the number of atoms.

The known reactive ion etching (RIE) technology causes an ion to move along a straight line through a plasma and an electric field and to impact a target in a high velocity with a very strong ion energy for the etching process. Accordingly, the known technology has a disadvantage that the ion impacts a substrate with a high energy to cause the surface of the substrate to be damaged. And also, the known etching technology proceeds by an interaction of a radical and the ion, and a radical absorption on the surface of the substrate and the ion irradiation occurs simultaneously. Therefore, the known technology has a problem that it is difficult for a processing precision with an atomic level to be obtained, because it is impossible to control the radical and the ion independently.

For solve such problem of the known technology, an atomic layer etching (ALE) technology has being developed actively. The radical absorption on the surface of the substrate and the ion irradiation may be controlled independently using the ALE process, and hence, the ALE technology may be expected as a technology capable of overcoming the limits of the known dry etching technology and accomplishing a process precision with an atomic level.

In the ALE process, a reactive gas may be adhered on a surface that needs to be etched, and the reactive gas may be removed with an ionic energy or a thermal energy. The ALE process removes an atom coupled to the etching layer to make a smooth surface physically. And also, the ALE process applies a technology that a sequential self-limit reaction is utilized for removing a thin layer, and the ALE technology is evaluated as the most promising technology to achieve a required low process variability in an atomic level.

At a first step of the ALE process mechanism, an etching gas may flow into a chamber to be absorbed on a thin membrane to be etched. The etching gas can use frequently a radical dissociated into a plasma for enhancing the absorption velocity, and when the etching gas is absorbed sufficiently to the thin film of a single layer, the absorption reaction is no longer occurs by the self-limiting. At a second step of the process mechanism, all of the residual gas except the absorbed etching gas may be removed, and a third step of the process mechanism may be divided into a plasma based ALE method where an inert ion with a low energy collides on the surface of the thin film and a thermal ALE method where the reactive surface layer on which the etching gas is absorbed is removed by applying a thermal energy to remove the layer of the absorbed surface. At the third step, if it is sufficient for the ion energy or the thermal energy to remove the chemically modified layer, but it is not sufficient to etch a basic bulk substance, then the reactive surface layer only may be removed by the self-limiting. Each method may be selected based on a reactive characteristic of the surface substance and a process profile.

At a fourth step of the ALE process mechanism, a process for removing etched by-products may be performed as a single cycle, and such cycle may be repeated for etching as a required thickness or a depth. The plasma based ALE technology can improve the absorption velocity using the dissipated radical and using the ion energy at the removing step. Hence, the plasma based ALE technology has an advantage that the process can be performed at a low temperature and the process time can be reduced. However, because the surface layer may be damaged by the plasma with a high energy and a gap of a sputtering threshold voltage between the bulk substance and the modified layer is very narrow, a considerable precise control technology of the ion energy may be required for a perfect self-limiting behavior. But the known art does not describe a technology to satisfy the requirements.

The present invention aims to provide a solution using a remote plasma and a DC pulse bias and has the following purposes.

### PURPOSE OF THE INVENTION

The object of the present invention is to provide with a substrate damage reducing type of an apparatus for etching an atomic layer using a remote plasma and a DC pulse bias.

### SUMMARY OF THE INVENTION

In an embodiment of the present invention, an apparatus for etching an atomic layer comprises a shower head for guiding a plasma generated from a remote plasma source into a chamber; a ceramic sheet placed on an upper surface of a supporting block on which a wafer is fixed, and having a plurality grooves; a temperature regulating block placed under the ceramic sheet; and a DC applying pin whose end part protrudes to at least one among the plurality of grooves.

In other embodiment of the present invention, the apparatus further comprises a gas supplying path formed to enable to supply an inert gas to the plurality of grooves.

In another embodiment of the present invention, the end part of the applying pin is received at a pin hole, and the pin hole is sealed.

In still another embodiment of the present invention, the gas supplying path is formed in a way to penetrate the temperature regulating block.

In still another embodiment of the present invention, the apparatus further comprises a DC pulse bias port for applying a DC pulse voltage to the DC applying pin, and a frequency, an amplitude, a duration, a phase or a duty cycle of the pulse power applied by the DC pulse bias port is controlled.

In still another embodiment of the present invention, the apparatus further comprises a lift ring capable of moving up and down.

In still another embodiment of the present invention, the lift ring rises upward at a removing step of an atomic layer etching process.

In still another embodiment of the present invention, the apparatus further comprises a moving gas wall installed above the shower head and capable of moving up and down.

In still another embodiment of the present invention, the DC applying pin contacts the substrate.

### BRIEF DESCRIPTION OF THE DRAWINGS

FIG. 1 shows an embodiment of a substrate damage reducing type of an apparatus for etching an atomic layer according to the present invention.

FIG. 2 shows an embodiment of a process to perform a self-limiting modification step corresponding to one process of the ALE method using the etching apparatus according to the present invention.

FIG. 3 shows an embodiment of a process to perform a removing step corresponding to one process of the ALE method using the etching apparatus according to the present invention.

FIG. 4 shows an embodiment of other process to perform a removing step corresponding to one process of the ALE method using the etching apparatus according to the present invention.

### DETAILED DESCRIPTION OF EXEMPLARY EMBODIMENTS

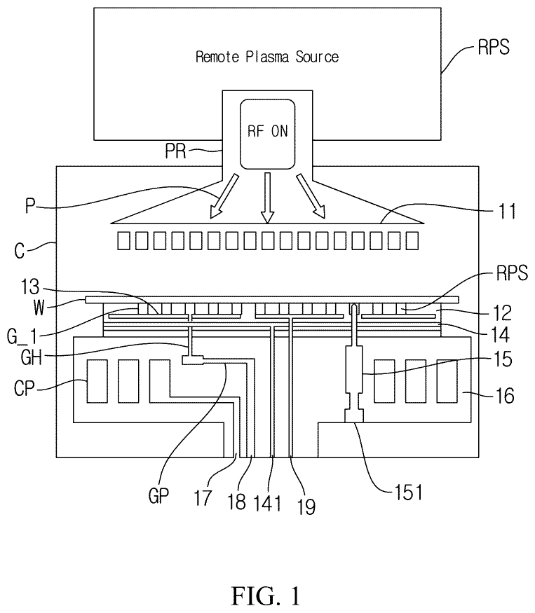

FIG. 1 shows an embodiment of a substrate damage reducing type of an apparatus for etching an atomic layer according to the present invention.

Referring to FIG. 1, an apparatus for etching an atomic layer, comprising: a shower head 11 for guiding a plasma generated from a remote plasma source RPS into a chamber C; a ceramic sheet 12 placed on an upper surface of a supporting block BD on which a wafer W is fixed, and having a plurality grooves G_1 to G_N; a temperature regulating block 16 placed under the ceramic sheet 12; and a DC applying pin 15 whose end part protrudes to at least one among the plurality of grooves G_1 to G_N.

The apparatus for etching the atomic layer may have a chamber structure, and the plasma may be generated at the remote plasma source RPS installed at an outside of the chamber. An inside of the chamber may become a vacuum state, and a chamber lid may be installed on an upper part of the chamber. The remote plasma source RPS may have a structure suitable for generating the plasma, and a gas for generating a plasma may be input into the remote plasma source PRS. The generated plasma may be guided above the shower head 11 installed within the chamber C through a plasma path RP formed for connecting the remote plasma source RPS to an upper part of the chamber.

The shower head 11 may have a function to guide the input plasma to the inside of the chamber C or an electrostatic chuck uniformly. The electrostatic chuck where a wafer is fixed may be installed under the shower head 11. The electrostatic chuck may comprise a ceramic sheet 12 having a function of a susceptor; and a temperature regulating block 16 formed under the ceramic sheet 12. The ceramic sheet 12 may have a structure to fixing the wafer W on its upper surface, and for example, the ceramic sheet 12 may have a circular plate shape or a cylindrical shape with a constant thickness. The ceramic sheet 12 may be made from various materials such as a ceramic material. Specifically, the ceramic sheet 12 may be made from an Alumina ceramic (Al2O3), but not limited to.

At least one groove G_1 to G_N may be formed on the upper surface of the ceramic sheet 12, and for example, a plurality of circular grooves G_1 to G_N with different diameters may be formed around the center of the ceramic sheet 12, and the different grooves G_1 to G_N may be connected for enabling the gas to flow through. At least one heater 13 with a circular plate shape may be arranged within the ceramic sheet 12 to regulate the temperature of the ceramic sheet 12 in course of an etching process. A power supplying line for supplying a power to the heater 13 may extend in a downward direction after penetrating the ceramic sheet 12 and the temperature regulating block 16. A heater power port 19 for supplying the power to the heater 13 may be formed at the lower part of the temperature regulating block 16. And a DC electrode plate 14 may be placed within the ceramic sheet 12, and a DC power may be applied through a DC electrode port 141. The wafer W may be fixed stably on the upper surface of the electrostatic chuck or the ceramic sheet 12 by the DC power applied to the DC electrode plate 14 through the DC electrode port 141.

A DC applying pin 15 may be arranged to contact a rear surface of the wafer W, whereby a DC voltage, preferably a DC pulse voltage, may be applied directly to the wafer W during the ALE process. The DC applying pin 15 may be formed in a way to penetrate the temperature regulating block 16 from the lower surface of the temperature regulating block 16 and protrude upward through one of the grooves G_1 to G_N formed at the ceramic sheet 12. The end part of the DC applying pin 15 protruding upward may be made as a needle shape and may contact the rear surface of the wafer W. The lower end part of the DC applying pin 15 may be positioned at the lower surface of the temperature regulating block 16 to form the DC supplying port 151. The pin hole where the upper end part of the DC applying pin 15 may be sealed in order that the inside of the chamber can be maintained as a vacuum state.

A DC pulse bias power, for example, may be applied through the DC supplying port 151, and a frequency, an amplitude, a duration, a phase or a duty cycle of the DC pulse bias power may be controlled. An energy of an ion generated from the remote plasma and incident onto the wafer W may be regulated through controlling such DC pulse bias power and parameters. For example, the wafer W may be fixed on the electrostatic chuck or the ceramic sheet 12 at the absorption step of the ALE process, and the self-limited modification reaction process may proceed at the surface of the wafer W by the ion or radical formed by the remote plasma. And also, the ion formed from the remote plasma source RPS may be incident on the surface of the wafer W to be absorbed on the surface of the wafer, and then the etching process may proceed at the absorbed surface of the wafer through a sputtering reaction. In this process, the DC pulse bias power whose parameters are controlled may be applied through the DC applying pin 15 for controlling the etching process efficiently. And this may allow the etching process to proceed with a width or a depth of a required level. At least one DC applying pin 15 may be arranged, and the present invention is not limited to the structure or the number of the DC applying pin 15.

A cooling path CP may be formed at the temperature regulating block 16 to circulate a coolant introduced through a coolant introducing port 17 for regulating the temperature of the ceramic sheet. For example, the temperature of the ceramic sheet 12 may be regulated in a range of 40 to 100° C. by the temperature regulating block 16, but not limited to. An inert gas such as He may be introduced to the at least one groove G_1 to G_N formed at the ceramic sheet 12, and for this purpose, a gas injecting port 18 may be formed at the temperature regulating block 16. A gas passage GH penetrating the temperature regulating block 16 from the gas injecting port 18 and connected to the at least one groove G_1 to G_N may be formed. A gas such as He may be injected through the gas injecting port 18 during the ALE process, and the injected gas may flow along the gas passage GH to be supplied to the at least one groove G_1 to G_N. A plurality of grooves G_1 to G_N may be formed on the upper surface of the ceramic sheet 12 in circular shapes with different diameters, and the grooves G_1 to G_N with different diameters may be connected each other in order that the gas can flow along the grooves G_1 to G_N. Grooves G_1 to G_N in various shapes may be formed in various numbers or at various depths, but not limited to.

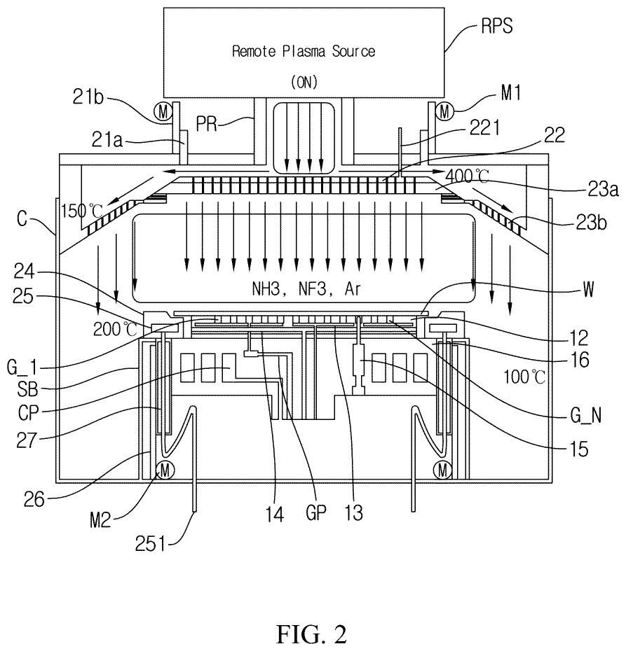

FIG. 2 shows an embodiment of a process to perform a self-limiting modification step corresponding to one process of the ALE method using the etching apparatus according to the present invention.

Referring to FIG. 2, the self-limited modification process for the ALE process may be performed at the etching apparatus, and the remote plasma generated from the remote plasma source RPS may be guided into the chamber C for the self-limited modification process.

The wafer W may be fixed on the upper ceramic sheet 12 corresponding to a susceptor, and the wafer W may be supported by a lift ring 24. The shower head may comprise an inner shower head 23a and a ring shaped outer shower head 23b extending obliquely in the downward direction from the perimeter of the inner shower 23a. An inner wall 21a with a hollow cylindrical shape may be formed at the cover of the chamber, and the inner wall 21a may move up and down along a pair of linear wall guide 21b arranged to face each other. A pair of driving motor M1 may be installed for operating each linear wall guide 21b, and the inner wall 21a may form a sealed volume between the inner shower head 23a and the cover of the chamber.

A plate shaped heater 22 may be placed above the inner shower head 23a to regulate the temperature of the inner shower head 23a and the outer shower head 23b. A power supplying port 221 for supplying a power to the heater 22 may be formed the upper part of the cover, and the temperature of the heater 22 may be regulated through the power supplying port 221. And the temperature of the inner shower head 23a and the outer shower head may be regulated by the heater 22. The temperature of the inner shower head 23a may be maintained at about 400° C. and the temperature of the outer shower head 23 may be maintained at about 150° C. at the step of the self-limited modification. The plasma guided above the inner shower head 23a may be distributed uniformly through the inner shower head 23a and the outer shower head 23b to be guided above the wafer W.

A ring heater 25 may be installed within the lift ring 24, and a power may be supplied to the ring heater 25 through the ring heater power port 251, and the temperature of the lift ring 25 may be regulated. For example, the temperature of the lift ring 24 may be maintained at about 200° C. during the step of the self-limited modification. The lift ring 24 may have a structure capable of moving up and down, and the lift ring 24 may be moved up and down by the up and down movement of a vertical moving unit 27. The lift ring may be fixed at the upper end of the vertical moving unit 27, and the vertical moving unit 27 may move along a linear guiding gear 26. In this way, the lift ring 24 may move up and down by a moving means having a structure of such as a rack and a pinion gear, and the vertical moving unit 27 may be rotated by a movement guiding motor M2 to move along the linear guiding gear 26. The wafer W may move up and down by the up and down movement of the lift ring 24, and hence the size of a volume formed between the shower head 23a, 23b and the wafer W may be regulated. The lift ring 24 may be maintained in a not-moving state at the step of the self-limited modification, and hence, the wafer W may be fixed on the upper surface of the ceramic sheet 12.

The temperature of the electrostatic chuck or the ceramic sheet 12 may be regulated by the coolant flowing along the cooling passage CP formed at the temperature regulating block 16, and the inner temperature of the chamber C may be maintained at about 100° C. by a heater placed within the chamber C. A gas such as NH3, NF3 or Ar together with the plasma may contact the wafer W at the step of the self-limited modification for performing an absorption reaction. And a removing step may be performed after the absorption reaction has been performed. At the removing step, a thermal removing method, which corresponds to an isotropic etching by an upper heating source in a state that the wafer W is lifted by the lift of the lift ring 24, or a plasma based removing method, which corresponds to an anisotropic etching that is performed by the remote plasma and the DC pulse bias, may be performed selectively. The atomic layer etching process by the remote plasma and the DC pulse may comprise a process to regulate an energy of ion incident on the wafer W by applying the DC pulse bias on the wafer W. Such process may become a directional etching method where the desired atomic layer is etched by regulating the ion energy. The thermal method and the plasma based method will be explained in detail below.

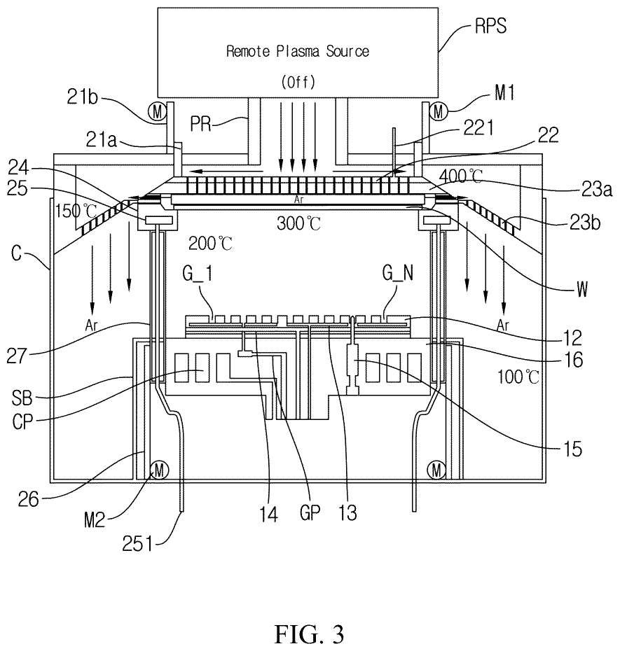

FIG. 3 shows an embodiment of a process to perform a removing step corresponding to one process of the ALE method using the etching apparatus according to the present invention.

Referring to FIG. 3, the pair of lift rings 24 may be lifted for applying the thermal removing method, and thus the wafer W may be separated from the ceramic sheet 12 and may move upward. The vertical moving unit 27 may be operated by driving the pair of movement guiding motors M2 to move upward along the linear guiding gear 26, and the pair of lift rings 24 may move upward to contact the lower part of the outer shower head 23b. Accordingly, the wafer W may be lifted to be positioned under the inner shower head 23a, and a removing volume can be formed between the lower surface of the inner shower head 23a and the upper surface of the wafer W. The inner wall 21a may move under the cover along the linear wall guide 21b by the operation of the pair of the driving motors M1, and the perimeter of the inner shower head 23a may be blocked by the inner wall 21a.

The operation of the remote plasma source RPS may be stopped, and hence an inflow of the plasma through the plasma passage PR may be halted, and Ar may be introduced through the plasma passage PR. Ar introduced above the inner shower head 23a may be guided to the removing volume formed between the lower part of the inner shower head 23a and the upper surface of the wafer W through a flowing hole formed uniformly at the inner shower head 23a. The temperature of the inner shower head 23a and the outer shower head 23b may be maintained at about 400° C. and 150° C., respectively, by the plate-shaped heater 22. And the temperature of the lift ring 24 may be regulated by ring heater 25 to be maintained at about 200° C. and the temperature of the lower part of the wafer W may be maintained at about 300° C. At the same time, the ceramic heater 12 may be placed at the upper part of the supporting block SB and the temperature regulating block 16 may be installed within the supporting block SB. And the surrounding temperature of the supporting block SB may be maintained at about 100° C. In such condition, Ar may contact the upper surface of the wafer W for the etching process, and Ar gas introduced to the removing volume for the etching process may be guided above the outer shower head 23b through a side of the volume or a gap formed at a middle part of the outer shower head 23b where the lift ring 24 contacts, and then Ar may move downward through guiding holes formed uniformly at the outer shower head 23b. The thermal removing process may be performed in various conditions, the presented temperature may be exemplary, but not limited to. As discussed above, the thermal removing method or the plasma based method may be performed selectively. The plasma based method will be discussed below.

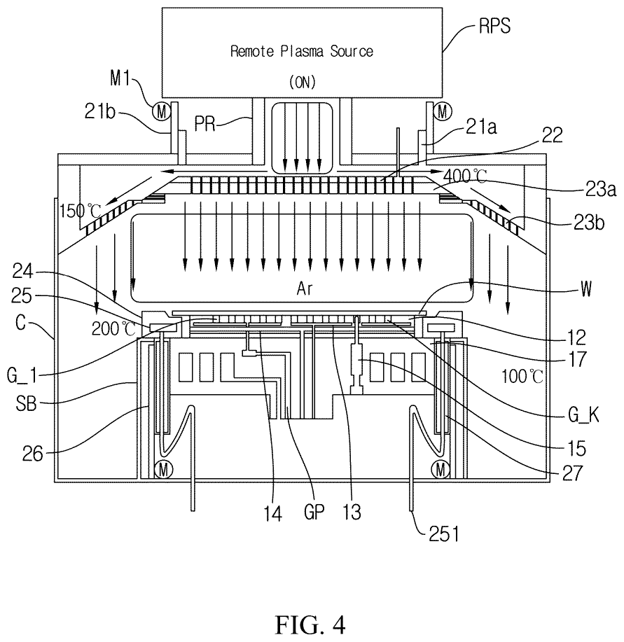

FIG. 4 shows an embodiment of other process to perform a removing step corresponding to one process of the ALE method using the etching apparatus according to the present invention.

Referring to FIG. 4, the wafer W may contact the upper surface of the ceramic sheet 12 to be fixed for applying the plasma based method of the ALE process. The plasma may be generated from the remote plasma source RPS to be guided above the inner shower head 23a through the plasma passage PR, and an Ar gas may be guided above the inner shower head 23a.

The plasma may flow within the chamber C through flowing holes formed at the inner shower head 23a, and the Ar gas may be guided via the inner shower head 23a and the outer shower head 23b. the temperature of the inner shower head 23 and the temperature of the outer shower head 23b may be maintained at about 400° C. and 150° C., respectively, and the temperature of the lift ring 24 may be maintained at about 200° C. by the ring heater 25. And also, the surrounding temperature of the supporting block SB may be maintained at about 100° C. In this condition, a DC pulse bias power with 1 to 500 V voltage may be applied to the DC applying pin 15 contacting the lower surface of the wafer W. the parameters of the DC pulse bias power such as a frequency, an amplitude, a duration, a phase or a duty cycle may be controlled. Hereby, the etching to the atomic layer may be performed as required. Thus, the etching apparatus according to the present invention may allow the plasma based removing method of the ALE process to be performed through the control of the DC pulse bias power as a required level. The removing process by the etching apparatus according to the present invention may be performed in various conditions, but not limited to.

What is claimed is:

1. An apparatus for etching an atomic layer, comprising:
a shower head for guiding a plasma generated from a remote plasma source into a chamber;
a ceramic sheet placed on an upper surface of a supporting block on which a wafer is fixed, and having a plurality grooves;
a temperature regulating block placed under the ceramic sheet; and
a DC applying pin whose end part protrudes to at least one among the plurality of grooves.

2. The apparatus according to claim 1, wherein the apparatus further comprises a gas supplying path formed to enable to supply an inert gas to the plurality of grooves.

3. The apparatus according to claim 1, wherein the end part of the DC applying pin is received at a pin hole, and the pin hole is sealed.

4. The apparatus according to claim 2, wherein the gas supplying path is formed in a way to penetrate the temperature regulating block.

5. The apparatus according to claim 1, wherein the apparatus further comprises a DC pulse bias port for applying a DC pulse voltage to the DC applying pin, and a frequency, an amplitude, a duration, a phase or a duty cycle of the pulse power applied by the DC pulse bias port is controlled.

6. The apparatus according to claim 1, wherein the apparatus further comprises a lift ring capable of moving up and down.

7. The apparatus according to claim 6, wherein the lift ring 24 rises upward at a removing step of an atomic layer etching process.

8. The apparatus according to claim 1, wherein the apparatus further comprises a moving gas wall installed above the shower head and capable of moving up and down.

9. The apparatus according to claim 1, wherein the DC applying pin contacts the substrate.
